(19) United States
(12) Patent Application Publication
(10) Pub. No.: US 2025/0369104 A1
(43) Pub. Date: Dec. 4, 2025

(54) METHOD FOR FORMING BARRIER LAYER

(71) Applicant: JUSUNG ENGINEERING CO., LTD., Gwangju-Si, Gyeonggi-Do (KR)

(72) Inventors: Il Hyong CHO, Gwangju-Si, Gyeonggi-Do (KR); Seung Chul SHIN, Gwangju-Si, Gyeonggi-Do (KR); Chul Joo HWANG, Gwangju-Si, Gyeonggi-Do (KR)

(21) Appl. No.: 18/568,799

(22) PCT Filed: Jun. 10, 2022
(86) PCT No.: PCT/KR2022/008222

§ 371 Date: Dec. 8, 2023

(30) Foreign Application Priority Data
Jun. 11, 2021 (KR) 10-2021-0076038

(51) Int. Cl. C23C 16/34; C23C 16/44; H01J 37/32; H01L 21/768

(52) U.S. Cl. CPC C23C 16/34; C23C 16/4408; H01J 37/3244; H01J 37/32522; H01L 21/76841; H01J 2237/332

(57) ABSTRACT

In accordance with an exemplary embodiment, a method for forming a barrier layer, which forms a barrier layer on a substrate by generating plasma, includes: injecting a NH₃-containing gas to be adsorbed onto the substrate; primarily purging of injecting a purge gas toward the substrate after the injecting of the NH₃-containing gas is stopped; generating plasma by using a H₂ gas; injecting a Ti-containing gas toward the substrate to form a TiN thin-film on the substrate; and secondarily purging of injecting a purge gas toward the substrate after the injecting of the Ti-containing gas is stopped, and the method form one process cycle of sequentially performing the injecting of the NH₃-containing gas, the primarily purging, the generating of the plasma, the injecting of the Ti-containing gas, and the secondarily purging. In accordance with exemplary embodiments, a barrier layer made of a TiN thin-film may be formed by an ALD method at a low temperature. Thus, the substrate or the thin-film formed on the substrate may be prevented from being damaged by high-temperature heat. Thus, a device including the barrier layer may be prevented from being defected or improved in performance. Also, impurities on the barrier layer may be removed by generating hydrogen plasma. Thus, degradation in quality of the device or the barrier layer caused by the impurities may be prevented.

### TECHNICAL FIELD

The present disclosure relates to a method for forming a barrier layer, and more particularly, to a method for forming a barrier layer, which forms a barrier layer in an atomic layer deposition method at a low temperature.

### BACKGROUND ART

Each of an integrated circuit device, a capacitor device, and the like includes a barrier layer formed between a dielectric layer and a conductive layer. Also, the barrier layer is formed of a TiN thin-film in an atomic layer deposition method. Here, a deposition process is performed in a state in which the inside of a chamber in which the deposition process is performed or a substrate on which the TiN thin-film is deposited maintains a high temperature of 350° C. or more. That is, when the inside of the chamber or the substrate maintains the high temperature of 350° C. or more, the TiN thin-film may be deposited onto the substrate.

However, when the TiN thin-film is formed at the high temperature, the substrate or the thin-film formed on the substrate may be damaged by heat. Also, this causes degradation in quality or performance of a device.

### RELATED ART DOCUMENT

### Patent Document

(patent document 1) Korean Patent Registration No. 10-0323268

### DISCLOSURE OF THE INVENTIVE CONCEPT

### Technical Problem

The present disclosure provides a method for forming a barrier layer, which forms a barrier layer made of a TiN thin-film by an atomic layer deposition method.

### Technical Solution

In accordance with an exemplary embodiment, a method for forming a barrier layer, which forms a barrier layer on a substrate by generating plasma, includes: injecting a NH₃-containing gas to be adsorbed onto the substrate; primarily purging of injecting a purge gas toward the substrate after the injecting of the NH3-containing gas is stopped; generating plasma by using a H₂ gas; injecting a Ti-containing gas toward the substrate to form a TiN thin-film on the substrate; and secondarily purging of injecting a purge gas toward the substrate after the injecting of the Ti-containing gas is stopped, and the method form one process cycle of sequentially performing the injecting of the NH₃-containing gas, the primarily purging, the generating of the plasma, the injecting of the Ti-containing gas, and the secondarily purging.

The process cycle may be repeatedly performed.

In accordance with another exemplary embodiment, a method for forming a barrier layer includes: injecting a Ti-containing gas to a process space in which a substrate is disposed; depositing a TiN thin-film on the substrate by injecting a NH₃-containing gas into the process space and generating plasma by using the NH₃-containing gas; and removing impurities on the TiN thin-film by injecting a H₂ gas into the process space and generating plasma by using the H₂ gas.

The generating of the plasma in each of the depositing of the TiN thin-film and the removing of the impurities may include applying a RF power to an injection unit configured to inject the NH₃-containing gas and the H₂-containing gas into the process space, and the RF power may be consecutively applied to the injection unit from the depositing of the TiN thin-film to the removing of the impurities.

The method may further include injecting a purge gas into the process space between the depositing of the TiN thin-film and the removing of the impurities.

Plasma may be generated by using the purge gas by applying a RF power to the injection unit when the purge gas is injected.

The method may further include pre-processing that is performed before the injecting of the Ti-containing gas, and the pre-processing may include: injecting a NH₃-containing gas into the process space so that the NH₃-containing gas is adsorbed onto the substrate; injecting a purge gas into the process space; and generating plasma by using a H₂ gas.

The method may further include adjusting a temperature of each of the process space and a support configured to support the substrate in the process space to be equal to or greater than 300° C. and less than 350° C.

### Advantageous Effects

In accordance with the exemplary embodiments, the barrier layer made of the TiN thin-film may be formed by the ALD method at the low temperature. Thus, the substrate or the thin-film formed on the substrate may be prevented from being damaged by the high-temperature heat. Thus, the device including the barrier layer may be prevented from being defected or improved in performance.

Also, the impurities on the barrier layer may be removed by generating the hydrogen plasma. Thus, the degradation in quality of the device or the barrier layer caused by the impurities may be prevented.

### BRIEF DESCRIPTION OF THE DRAWINGS

FIG. 1 is a view illustrating a portion of a device including a TiN thin-film formed by a method in accordance with an exemplary embodiment;

FIG. 2 is a conceptual view for explaining a method for forming a TiN thin-film by the method in accordance with an exemplary embodiment;

FIG. 3 is a conceptual view for explaining a method for forming a TiN thin-film by the method in accordance with another exemplary embodiment; and

FIG. 4 is a schematic view illustrating a deposition apparatus used for forming a TiN thin-film or a barrier layer in accordance with exemplary embodiments.

### MODE FOR CARRYING OUT THE INVENTIVE CONCEPT

Hereinafter, exemplary embodiments will be described in more detail with reference to the accompanying drawings. The present inventive concept may, however, be embodied in different forms and should not be construed as limited to the embodiments set forth herein. Rather, these embodiments are provided so that this disclosure will be thorough and complete, and will fully convey the scope of the present inventive concept to those skilled in the art. In the figures, the dimensions of layers and regions are exaggerated for clarity of illustration. Like reference numerals refer to like elements throughout.

Exemplary embodiments relates to a method for forming a barrier layer made of a TiN thin-film. Specifically, the exemplary embodiments relates to a method for forming a barrier layer by depositing a TiN thin-film at a temperature less than 350° C. More specifically, the exemplary embodiments relates to a method for forming a barrier layer by depositing a TiN thin-film at a low temperature equal to or greater than 300° C. and less than 350° C. in an atomic layer deposition (ALD) method.

Also, the TiN thin-film formed by a method in accordance with exemplary embodiments may be a barrier layer disposed between a dielectric layer and a conductive layer to perform an insulation function. More specifically, the TiN thin-film in accordance with exemplary embodiments may be a barrier layer formed between a dielectric layer and a conductive layer in an integrated circuit device or a capacitor device.

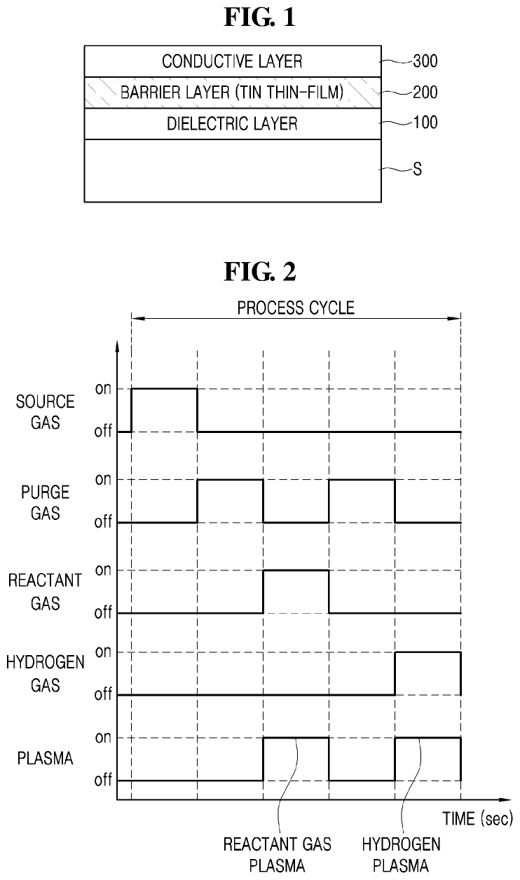

FIG. 1 is a view illustrating a portion of a device including a TiN thin-film formed by a method in accordance with an exemplary embodiment. FIG. 2 is a conceptual view for explaining a method for forming a TiN thin-film by the method in accordance with an exemplary embodiment. Here, FIG. 1 is a conceptual view illustrating a portion of an integrated circuit device including the barrier layer disposed between the dielectric layer and the conductive layer and illustrating a state in which the barrier layer is made of the TiN thin-film formed by the method in accordance with an exemplary embodiment.

Referring to FIG. 1, a device including a barrier layer 200 formed by the method in accordance with an exemplary embodiment may include a substrate S, a dielectric layer 100 formed on the substrate S, a barrier layer 200 disposed on the dielectric layer 100 and made of a TiN thin-film, and a conductive layer 300 disposed on the barrier layer 200.

The substrate S may be a semiconductor substrate. Specifically, for example, the substrate may be a Si wafer, a GaAs wafer, and SiGe wafer.

The dielectric layer 100 is disposed on the substrate S. Here, the dielectric layer 100 may be made of a metal oxide. Specifically, for example, the dielectric layer 100 may be made of one of ZrO₂, Al₂O₃, TiO₂, TaO₂, and HfO₂. Also, the dielectric layer 100 may be formed by an atomic layer deposition (ALD) method or a chemical vapor deposition (CVD) method.

The barrier layer 200 may be a layer formed on the dielectric layer 100 and made of a TiN thin-film. That is, the barrier layer 200 is a layer formed after the dielectric layer 100 is formed on the substrate S and before the conductive layer 300 is formed and made of the TiN thin-film. Here, the barrier layer 200, i.e., the TiN thin-film, is formed by the ALD method.

As described above, the TiN thin-film is formed between the dielectric layer 100 and the conductive layer 300, and the TiN thin-film is the barrier layer 200. Thus, each of the TiN thin-film and the barrier layer may be indicated by the same reference numeral ‘200’. That is, the reference numeral ‘200’ indicates the TiN thin-film and the barrier layer.

When the barrier layer 200 is formed by the atomic layer deposition method, plasma is generated when injection of a reactant gas is stopped or finished. That is, plasma is generated by using a hydrogen gas when the injection of the reactant gas is stopped or finished.

Hereinafter, a method for forming the TiN thin-film or the barrier layer 200 made of the TiN thin-film by the ALD method will be described with reference to FIG. 2. Here, in FIG. 2, a term ‘on’ represents a feature of injecting a gas and generating plasma, and a term ‘off’ represents a feature of stopping or finishing the injecting of the gas or stopping the generating of the plasma or a state in which the plasma is not generated.

Referring to FIG. 2, the forming of the TiN thin-film may include: injecting a source gas; stopping the injecting of the source gas and then injecting a purge gas (primary purging); stopping the injecting of the purge gas and then injecting a reactant gas; stopping the injecting of the reactant gas and then injecting a purge gas (secondary purging); and stopping the injecting of the purge gas and then forming hydrogen plasma. Here, a Ti-containing gas may be used as the source gas, an N-containing gas may be used as the reactant gas, and an argon (Ar) gas may be used as the purge gas. Here, the Ti-containing gas may include a TiCl₄-containing gas, and the reactant gas may include a NH₃-containing gas.

In an exemplary embodiment, the injecting of the reactant gas generates plasma. That is, as the reactant gas is discharged by applying a RF power when the reactant gas is injected, reactant gas plasma is generated.

Also, hydrogen plasma is generated when the injection of the reactant gas is stopped or finished. That is, the hydrogen plasma (hydrogen gas plasma) is generated by injecting a hydrogen gas after the injecting of the reactant gas is finished and applying the RF power to discharge the hydrogen gas. Here, the generating of the hydrogen plasma may be performed after the reactant gas is injected and the secondary purging is finished.

The above-described ‘the injecting of the source gas-the injecting of the purge gas (the primary purging)—the injecting of the reactant gas (the generating of the plasma)—the injecting of the purge gas (the secondary purging)-the generating of the hydrogen plasma’ may form one process cycle for forming the TiN thin-film. Also, as the above-described process cycle is repeated a plurality of times, the ALD is performed a plurality of times. Also, as the performance number of the process cycle is adjusted, the TiN thin-film having a target thickness may be formed.

The above-described process cycle including ‘the injecting of the source gas—the injecting of the purge gas (the primary purging)—the injecting of the reactant gas (the generating of the plasma)—the injecting of the purge gas (the secondary purging)—the generating of the hydrogen plasma’ is returned to the injecting of the source gas after the generating of the hydrogen plasma is finished. However, the exemplary embodiment is not limited thereto. For example, injecting of a purge gas (tertiary purging) may be additionally performed after the generating of the hydrogen plasma. That is, ‘the injecting of the source gas—the injecting of the purge gas (the primary purging)—the injecting of the reactant gas (the generating of the plasma)—the injecting of the purge gas (the secondary purging)—the generating of the hydrogen plasma—the injecting of the purge gas (the tertiary purging)’ may form one process cycle for forming the TiN thin-film.

In the above-described process cycle, when the source gas is injected, the source gas is adsorbed onto the dielectric layer. Also, when plasma is generated by injecting the reactant gas after the injecting of the purge gas (the primary purging), the reactant gas (the NH₃-containing gas) and the source gas (the TiCl₄-containing gas) adsorbed onto the dielectric layer 100 react to produce a reactant, i.e., TiN. Also, this reactant is accumulated or deposited onto the dielectric layer 100, and thus a thin-film made of TiN is formed on the dielectric layer 100. That is, the barrier layer 200 made of the TiN thin-film is formed on the dielectric layer 100.

Typically, when the TiN thin-film is formed by the ALD method, a temperature of the process space in which a deposition process is performed, e.g., the inside of a chamber or a substrate S on which the TiN thin-film is deposited is maintained at a high temperature equal to or greater than 350° C. In other words, only when the inside of the chamber or the substrate S maintains a high temperature equal to or greater than 350° C., the TiN thin-film may be deposited on the substrate S or the dielectric layer 100. However, when the TiN thin-film is formed at a high temperature as stated above, a lower layer formed below the substrate S or the TiN thin-film, e.g., the dielectric layer 100, may be damaged by heat. Also, this cause degradation of a quality or performance of the device.

However, in accordance with an exemplary embodiment, plasma is generated when the TiN thin-film is formed or deposited by the ALD method. That is, plasma is generated by applying the RF power in the injecting of the reactant gas. The plasma generated when the reactant gas is injected may improve a reaction efficiency between the source gas and the reactant gas and allow the reactant produced from the reaction between the source gas and the reactant gas to be easily deposited or attached onto the substrate S or the dielectric layer 100. Thus, the TiN thin-film may be formed by the ALD method in a state in which the inside of the chamber or the substrate S has a low temperature, e.g., a temperature less than 350° C. That is, the TiN thin-film may be formed at the low temperature less than 350° C. instead of forming the TiN thin-film in a state in which the substrate S is heated at a high temperature as in the related art. Thus, the lower support layer disposed below the substrate S or the TiN thin-film may be prevented from being damaged by high-temperature heat.

Also, when the injecting of the reactant gas is stopped, hydrogen plasma is generated. That is, the hydrogen plasma is generated by injecting the hydrogen gas and applying the RF power to the process space when the injecting of the reactant gas is finished to discharge the hydrogen gas. The hydrogen plasma generated at this time may remove impurities. Here, for example, the impurities may be reaction by-products produced from the reaction between the source gas and the reactant gas. Specifically, for example, the impurities may be Cl (impurities) produced from a reaction between TiCl₄ contained in the source gas and NH₃ contained in the reaction gas. Also, when the hydrogen plasma is generated in the process space, hydrogen H₂ reacts with impurities, e.g., Cl, to form HCl in a gas phase. Also, the HCl gas is discharged to the outside through an exhaust part connected to the reaction space. Here, the plasma generated by the hydrogen gas facilitates or accelerates the reaction between the hydrogen and the impurities, e.g., Cl. Thus, as the hydrogen plasma is generated after the reactant gas is injected, the impurities existing in the process space may be effectively removed. Thus, pollution caused by the impurities when the TiN thin-film, i.e., the barrier layer 200, is formed may be prevented or suppressed, and the performance of the device may be improved.

The conductive layer 300 is formed on the barrier layer (the TiN thin-film) 200. Here, the conductive layer 300 may be made of metal or a material containing metal. For example, the conductive layer 300 may be made of at least one material of Cu, Au, Ag, Ti, Ta, Co, and Pt. For example, the conductive layer 300 may be made of at least one material of Cu, Au, Ag, Ti, Ta, Co, and Pt. Also, the conductive layer 300 may be formed by the ALD method or the CVD method.

The feature in which the barrier layer 200 of the integrated circuit device is made of the TiN thin-film is explained above. However, the exemplary embodiment is not limited to the integrated circuit device. For example, the device including the barrier layer 200 made of the TiN thin-film may be applied to various devices that require the barrier layer 200, e.g., a capacitor device including a barrier layer.

The method for forming the barrier layer in accordance with an exemplary embodiment has one process cycle of ‘the injecting of the source gas—the injecting of the purge gas (the primary purging)—the injecting of the reactant gas (the generating of the plasma)—the injecting of the purge gas (the secondary purging)—the generating of the hydrogen plasma’.

Here, the process cycle may include a pre-processing that is performed before the injecting of the hydrogen gas. Also, the pre-processing may include injecting a reactant gas, injecting a purge gas after the injecting of the reactant gas is stopped, and generating hydrogen plasma after the injecting of the purge gas is stopped. Here, the reactant gas may be a NH₃-containing gas. That is, the pre-processing including the injecting of the reactant gas, the injecting of the purge gas, and the generating of the hydrogen plasma may be performed before the process cycle including ‘the injecting of the source gas—the injecting of the purge gas (the primary purging)—the injecting of the reactant gas (the generating of the plasma)—the injecting of the purge gas (the secondary purging)—the generating of the hydrogen plasma’.

Also, the pre-processing may be performed only before the process cycle is initially performed, but pre-processing may not be performed after the process cycle. That is, when the pre-processing is finished, the process cycle is firstly performed, and when the firstly performed process cycle is finished, the source gas is injected for secondarily performing the process cycle instead of returning to the pre-processing.

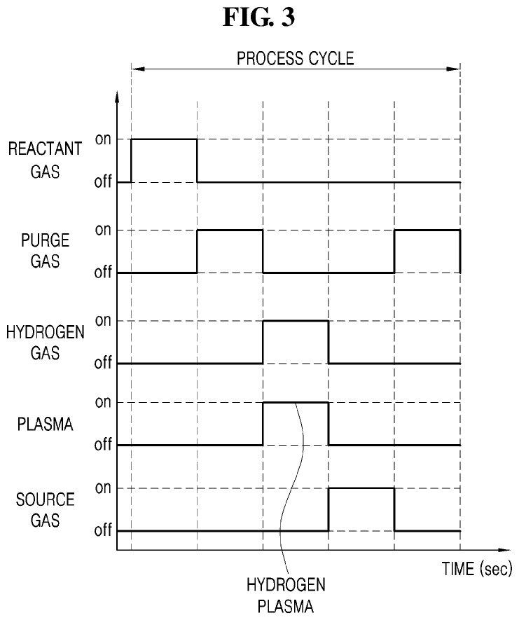

FIG. 3 is a conceptual view for explaining a method for forming a TiN thin-film in accordance with another exemplary embodiment.

The method for forming the TiN thin-film in accordance with another exemplary embodiment forms the TiN thin-film by the ALD method and has a different order of injecting a source gas and a reactant gas. That is, as illustrated in FIG. 3, the method for forming the TiN thin-film in accordance with another exemplary embodiment may include injecting a reactant gas, injecting a purge gas after the injecting of the reactant gas is stopped (primary purging), generating hydrogen plasma after the injecting of the purge gas is stopped, and injecting a purge gas after the generating of the hydrogen plasma is stopped (secondary purging).

In accordance with another exemplary embodiment, generation of plasma may be omitted when the reactant gas is injected. Also, a hydrogen gas is injected to generate the hydrogen plasma after the injecting of the reactant gas and the primary purging.

The above-described ‘the injecting of the reactant gas-the injecting of the purge (the primary purging)—the generating of the hydrogen plasma—the injecting of the source gas—the injecting of the purge gas (the secondary purging)’ may form one process cycle for forming the TiN thin-film.

The source gas, the reactant gas, and the purge gas may be the same as those described in an exemplary embodiment. That is, a Ti-containing gas may be used as the source gas, a N-containing gas may be used as the reactant gas, and an argon (Ar) gas may be used as the purge gas. Here, the Ti-containing gas may include a TiCl₄-containing gas, and the reactant gas may include a NH₃-containing gas.

As described above, the method in accordance with another exemplary embodiment injects the reactant gas before the injecting of the source gas to generate the hydrogen plasma. As the hydrogen plasma is generated after the injecting of the reactant gas, a deposition rate or a film quality of the TiN thin-film may be improved. That is, as the hydrogen plasma is generated after the injecting of the reactant gas, ionization of the reactant gas may increase. Thus, an amount of the ionized reactant gas adsorbed onto the substrate S may increase. Thus, an amount of the source gas reacting with the reactant gas adsorbed onto the substrate S may increase. Thus, the deposition rate and the film quality of the TiN thin-film may be improved.

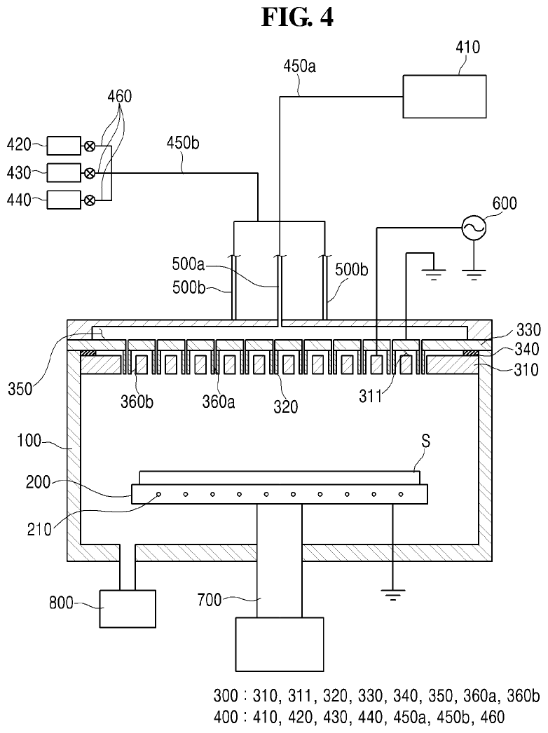

FIG. 4 is a schematic view illustrating a deposition apparatus used for forming the TiN thin-film or the barrier layer in accordance with exemplary embodiments.

The deposition apparatus may deposit a thin-film by the ALD method. As illustrated in FIG. 4, the deposition apparatus may include a chamber 100, a support 200 installed in the chamber 100 to support a substrate S, an injection unit 300 disposed to face the support 200 and injecting a gas for a process (hereinafter, referred to as a process gas) into the chamber 100, a gas supply unit 400 for providing the process gas to the injection unit 300, first and second gas supply pipes 500a and 500b connected to the injection unit 300 to have different paths and supplying a gas provided from the gas supply unit 400 to the injection unit 300, and a RF power unit 600 for applying a power to generate plasma in the chamber 100.

Also, the deposition apparatus may include a driving unit 700 for operating the support 200 to perform at least one of elevation and rotation and an exhaust unit 800 connected to the chamber 100 to exhaust the inside of the chamber 100.

The chamber 100 may include an inner space in which a thin-film is formed on the substrate S loaded into the chamber 100. For example, the inner space may have a cross-sectional shape of a rectangular shape, a pentagonal shape, and a hexagonal shape. Alternatively, the inner space of the chamber 100 may have various shapes in correspondence to a shape of the substrate S.

The support 200 may be installed in the chamber 100 to face the injection unit 300 and support the substrate S loaded into the chamber 100. A heater 210 may be provided in the support 200. Thus, when the heater 210 is operated, the substrate S seated on the support 200 and the inside of the chamber 100 may be heated.

Also, a separate heater may be provided outside or inside the chamber 100 in addition to the heater 210 disposed in the support 200 as a unit for heating the substrate S or the inside of the chamber 100.

The injection unit 300 may include a first plate 310 disposed in the chamber 100 to face the support 200 and having a plurality of holes (hereinafter, referred to as holes 311) that are spaced apart from each other and arranged in an extension direction of the support 200, a plurality of nozzles 320 at least partially inserted to the plurality of holes 311, respectively, and a second plate 330 disposed between the first plate 310 and an upper wall in the chamber 100.

Also, the injection unit 300 may further include an insulation part 340 disposed between the first plate 310 and the second plate 330.

Here, the first plate 310 may be connected to the RF power unit 600, and the second plate 330 may be grounded. Also, the insulation part 340 may serve to prevent an electrical connection between the first plate 310 and the second plate 330.

The first plate 310 may have a plate shape extending in the extension direction of the support 200. Also, when the plurality of holes 311 are defined in the first plate 310, each of the plurality of injection holes 311 may pass through the first plate 310 in a vertical direction. Also, the plurality of holes 311 may be arranged in the extension direction of the support 200 or the first plate 310.

Each of the plurality of nozzles 320 may have a shape extending in the vertical direction, a passage through which a gas passes is defined in each thereof, and an upper end and a lower end thereof are opened. Also, each of the plurality of nozzles 320 has at least a lower portion inserted to the hole 311 defined in the first plate 310 and an upper portion connected to the second plate 330. Thus, each of the nozzles 320 may have a shape protruding downward from the second plate 330.

The nozzle 320 may have an external diameter less than an internal diameter of the hole 311. Also, when the nozzle 320 is inserted into the hole 311, an outer circumferential surface of the nozzle 320 may be spaced apart from a surrounding wall (i.e., an inner wall of the first plate 310) of the hole 311. Thus, the inside of the hole 311 may be divided into an outer space and an inner space of the nozzle 320.

In the inner space of the hole 311, the inner space of the nozzle 320 is a passage through which a gas provided from the first gas supply pipe 500a is moved and injected. Also, in the inner space of the hole 311, the outer space of the nozzle 320 is a passage through which a gas supplied from the second gas supply unit 500b is moved and injected. Thus, hereinafter, the passage in the nozzle 320 is referred to as a first path 360a, and the outer space of the nozzle 320 in the hole 311 is referred to as a second path 360b.

The second plate 330 may have a top surface spaced apart from the upper wall in the chamber 100 and a bottom surface spaced apart from the first plate 310. Thus, an empty space may be defined between the second plate 330 and the first plate 310 and between the second plate 330 and the upper wall in the chamber 100.

Here, an upper space of the second plate 330 may be a space (hereinafter, referred to as a diffusion space 350) in which the gas provided from the first gas supply pipe 500a is diffused and moved and which communicates with upper openings of the plurality of nozzles 320. In other words, the diffusion space 350 communicates with the plurality of first paths 360a. Thus, the gas passing through the first gas supply pipe 500a may be diffused from the diffusion space 350 in an extension direction of the second plate 330 and then injected downward through the plurality of first paths 360a.

Also, a gun drill (not shown) that is a passage through which a gas is moved may be defined in the second plate 330, and the gun drill may be connected with the second gas supply pipe 500b and communicate with the second path 360b. Thus, the gas provided from the second gas supply unit 500 may be injected toward the substrate S through the gun drill and the second path 360b of the second plate 330.

The gas supply unit 400 provides a gas necessary for depositing a thin-film in the ALD method. The gas supply unit 400 may include: a source gas storage 410 in which a source gas is stored; a reactant gas storage 420 in which a reactant gas reacting with the source gas is stored; a purge gas storage 430 in which a purge gas is stored; a hydrogen gas storage 440 in which a hydrogen gas is stored; a first transfer pipe 450a installed to connect the source gas storage 410 with the first gas supply pipe 500a; and a second transfer pipe 450b installed to connect the second gas supply pipe 500b with each of the reactant gas storage 420, the purge gas storage 430, and the hydrogen gas storage 440.

Also, the gas supply unit 400 may include a connection pipe 460 for connecting the second transfer pipe 450b with each of the each of the reactant gas storage 420, the purge gas storage 430, and the hydrogen gas storage 410 and a valve installed on each of the first transfer pipe 450a and a plurality of connection pipes 460.

Hereinafter, the method for forming the barrier layer made of the TiN thin-film in accordance with an exemplary embodiment will be described with reference to FIGS. 1, 2, and 4. Here, the method for forming the barrier layer on the dielectric layer will be described as an example.

First, the support 200 is heated by operating the heater 210 disposed in the support 200. Here, the heater 210 is operated so that the support 200 or the substrate S seated on the support 200 has a temperature equal to or greater than 300° C. and less than 350° C. Specifically, for example, the heater 210 is operated so that the substrate S has a temperature of 300° C.

Thereafter, the substrate S on which the dielectric layer 100 is formed is loaded into the chamber 100 and seated on the support 200. Thereafter, when the substrate S seated on the support 200 has a target process temperature of 300° C., the barrier layer 200 made of the TiN thin-film is formed on the dielectric layer 100.

Here, the barrier layer 200 is formed by using the ALD method. Also, the ALD method performs in an order of injecting a source gas, injecting a purge gas (primary purging), injecting a reactant gas, injecting a purge gas (secondary purging), and generating hydrogen plasma, and plasma is generated when the reactant gas is injected. That is, a process cycle of forming the barrier layer 200 by the ALD method may be ‘the injecting of the source gas—the injecting of the purge gas (the primary purging)—the injecting of the reactant gas (the generating of the plasma)—the injecting of the purge gas (the secondary purging)—the generating of the hydrogen plasma’. Also, the process cycle is repeated a plurality of times to form the barrier layer 200 having a target thickness.

Hereinafter, a method for forming the barrier layer 200 by injecting a gas into the chamber 100 using the injection unit 300 and the gas supply unit 400.

First, a source gas is injected into the chamber 100. To this end, a TiCl₄-containing gas stored in the source gas storage 410 is supplied to the first transfer pipe 450a. The source gas is introduced into the diffusion space 350 in the injection unit 300 through the first transfer pipe 4501 and the first gas supply pipe 500a. Also, the source gas is diffused in the diffusion space 350 and then injected toward the substrate S through the plurality of nozzles 320, i.e., the plurality of first paths 360a.

After the source gas is injected for a predetermined time, the injecting of the source gas is stopped. Also, when the injecting of the source gas is stopped or finished, the purge gas is supplied from the purge gas storage 430 and injected into the chamber 100 (the primary purging). Here, the purge gas supplied from the purge gas storage 430 may pass through the connection pipe 460, the second transfer pipe 450b, and the second gas supply pipe 500b and then be injected downward through the second path 360b.

Thereafter, the reactant gas, e.g., a NH₃-containing gas, is supplied from the reactant gas storage 420 and injected into the chamber 100. Here, the reactant gas may be injected into the chamber 100 through the same path as the purge gas. That is, the reactant gas may pass through the connection pipe 460, the second transfer pipe 450b, and the second gas supply pipe 500b and then be injected downward through the second path 360b. When the reactant gas is injected, a reaction may be generated between the reaction gas and the source gas adsorbed onto the dielectric layer 100 to produce a reactant, i.e., TiN. Also, this reactant is accumulated or deposited onto the dielectric layer 100, and thus a thin-film made of TiN is formed on the substrate S.

When the reactant gas is injected into the chamber 100, the RF power unit 600 is operated to apply a RF power to the first plate 310. Accordingly, plasma caused by the reactant gas is generated.

The plasma generated when the reactant gas is injected may improve a reaction efficiency between the source gas and the reactant gas and allow the reactant produced from the reaction between the source gas and the reactant gas to be easily deposited or attached onto the dielectric layer 100. In other words, although the inside of the chamber 100 or the substrate S heated by the heater 210 has a low temperature less than 350° C., the reaction between the reactant gas and the source gas may be easily implemented by the plasma generated when the reactant gas is injected. Thus, the TiN thin-film may be formed by the ALD method in a state in which the inside of the chamber 100 or the substrate S has a low temperature, e.g., a temperature less than 350° C. That is, the TIN thin-film may be formed at the low temperature less than 350° C. instead of forming the TIN thin-film in a state in which the substrate S is heated at a high temperature as in the related art. Thus, the lower support layer disposed below the substrate S or the TiN thin-film may be prevented from being damaged by high-temperature heat.

After the reactant gas is injected for a predetermined time, the injecting of the reactant gas is stopped. Also, when the injecting of the reactant gas is stopped or finished, the purge gas is supplied from the purge gas storage 430 and injected into the chamber 100 (the secondary purging). Here, a reactant produced from the reaction between the source gas and the reactant gas may be discharged outside the chamber 100 by the secondary purging.

When the secondary purging is finished, the hydrogen gas is injected into the chamber 100. Here, the hydrogen gas may be injected into the chamber 100 through the same path as the purge gas. That is, the hydrogen gas may pass through the connection pipe 460, the second transfer pipe 450b, and the second gas supply pipe 500b and then be injected downward through the second path 360b. When the hydrogen gas is injected, the RF power unit 600 is operated to apply a RF power to the first plate 310. Accordingly, plasma using the hydrogen gas, i.e., hydrogen plasma, is generated in the chamber 100.

The hydrogen plasma generated at this time may remove impurities remained in the chamber 100. For example, Cl (impurities) that is reaction by-products produced from a reaction between TiCl₄ contained in the source gas and NH₃ contained in the reaction gas and remained in the chamber 100 or remained on the TiN thin-film react with hydrogen to produce HCl. Here, the plasma generated by the hydrogen gas accelerates a reaction between hydrogen and Cl. Also, the HCl gas is discharged to the outside through the exhaust part connected to the chamber. Thus, pollution caused by the impurities when the TiN thin-film, i.e., the barrier layer 200, is formed may be prevented or suppressed, and the performance of the device may be improved.

The above-described process cycle of ‘the injecting of the source gas—the injecting of the purge gas (the primary purging)—the injecting of the reactant gas (the generating of the plasma)—the injecting of the purge gas (the secondary purging)—the generating of the hydrogen plasma’ may be repeated a plurality of times. Also, the performance number of the process cycle may be determined according to a target thickness. Also, injecting a purge gas (tertiary purging) may be added between the generating of the hydrogen plasma and the injecting of the source gas.

Also, it is described above that the plasma is generated in the injecting of the reactant gas and the injecting of the hydrogen gas, and the plasma is not generated in the secondary purging. However, the exemplary embodiment is not limited thereto. For example, plasma may be generated in the secondary purging by using the purge gas, i.e., the argon (Ar) gas. In other words, the RF power may be consecutively applied from the injecting of the reactant gas to the injecting of the hydrogen gas. Thus, the plasma may be consecutively generated in the injecting of the reactant gas, the injecting of the purge gas (the secondary purging), and the generating of the hydrogen plasma.

When the TiN barrier layer 200 having the target thickness is formed, the conductive layer 300 is formed on the barrier layer 200. Here, the conductive layer 300 may be formed by the ALD method or the CVD method and made of one of Cu, Au, Ag, Ti, Ta, Co, and Pt or a material containing at least one thereof.

In accordance with exemplary embodiments, the TiN thin-film, i.e., the TiN barrier layer 200 may be formed at the low temperature less than 350° C. Thus, the lower layer or the substrate on which the TiN thin-film is formed may be prevented from being damaged. Also, the impurities on the barrier layer may be removed by generating the hydrogen plasma, and thus the quality of the barrier layer or the device may be improved.

### INDUSTRIAL APPLICABILITY

In accordance with the exemplary embodiments, the barrier layer made of the TIN thin-film may be formed by the ALD method at the low temperature. Thus, the substrate or the thin-film formed on the substrate may be prevented from being damaged by the high-temperature heat. Thus, the device including the barrier layer may be prevented from being defected or improved in performance.

Also, the impurities on the barrier layer may be removed by generating the hydrogen plasma. Thus, the degradation in quality of the device or the barrier layer caused by the impurities may be prevented.

1. A method for forming a barrier layer, which forms a barrier layer on a substrate by generating plasma, comprising:
injecting a NH₃-containing gas to be adsorbed onto the substrate;
primarily purging of injecting a purge gas toward the substrate after the injecting of the NH₃-containing gas is stopped;
generating plasma by using a H₂ gas;
injecting a Ti-containing gas toward the substrate to form a TiN thin-film on the substrate; and
secondarily purging of injecting a purge gas toward the substrate after the injecting of the Ti-containing gas is stopped,
wherein the method form one process cycle of sequentially performing the injecting of the NH₃-containing gas, the primarily purging, the generating of the plasma, the injecting of the Ti-containing gas, and the secondarily purging.

2. The method of claim 1, wherein the process cycle is repeatedly performed.

3. A method for forming a barrier layer, comprising:
injecting a Ti-containing gas to a process space in which a substrate is disposed;
depositing a TiN thin-film on the substrate by injecting a NH₃-containing gas into the process space and generating plasma by using the NH₃-containing gas; and
removing impurities on the TiN thin-film by injecting a H₂ gas into the process space and generating plasma by using the H₂ gas.

4. The method of claim 3, wherein the generating of the plasma in each of the depositing of the TiN thin-film and the removing of the impurities comprises applying a RF power to an injection unit configured to inject the NH₃-containing gas and the H₂-containing gas into the process space,
wherein the RF power is consecutively applied to the injection unit from the depositing of the TiN thin-film to the removing of the impurities.

5. The method of claim 4, further comprising injecting a purge gas into the process space between the depositing of the TiN thin-film and the removing of the impurities.

6. The method of claim 5, wherein plasma is generated using the purge gas by applying a RF power to the injection unit when the purge gas is injected.

7. The method of claim 3, further comprising pre-processing that is performed before the injecting of the Ti-containing gas,
wherein the pre-processing comprises:
injecting a NH₃-containing gas into the process space so that the NH₃-containing gas is adsorbed onto the substrate;
injecting a purge gas into the process space; and
generating plasma by using a H₂ gas.

8. The method of claim 3, further comprising adjusting a temperature of each of the process space and a support configured to support the substrate in the process space to be equal to or greater than 300° C. and less than 350° C.
